(19) United States
(12) Patent Application Publication
(10) Pub. No.: US 2014/0224175 A1
(43) Pub. Date: Aug. 14, 2014

(54) GAS DISTRIBUTION MANIFOLD SYSTEM FOR CHEMICAL VAPOR DEPOSITION REACTORS AND METHOD OF USE

(71) Applicant: MEMC ELECTRONIC MATERIALS, INC., St. Peters, MO (US)

(72) Inventor: Arash Abedijaberi, St. Peters, MO (US)

(73) Assignee: MEMC ELECTRONIC MATERIALS, INC., St. Peters, MO (US)

(21) Appl. No.: 13/767,393

(22) Filed: Feb. 14, 2013

(51) Int. Cl. C23C 16/455; B23P 11/00

(52) U.S. Cl. CPC C23C 16/455; B23P 11/00
USPC 118/719; 137/597; 29/428

(57) ABSTRACT

A gas distribution manifold for a chemical vapor deposition reactor includes a first gas distribution zone including a central gas port located in a central portion of the manifold. The manifold also includes a second gas distribution zone including at least two intermediate ports adjacent the central gas port. The manifold further includes a third gas distribution zone including at least two outer ports, each one of the outer ports spaced from the central gas port by one of the intermediate ports. The gas distribution manifold includes a fourth gas distribution zone comprising at least two edge ports, each edge port being spaced from the central outlet port by at least one of the intermediate and outer ports.

### FIELD

The field relates generally to chemical vapor deposition processes, and more particularly to gas distribution manifolds and related controllers and methods for controlling the uniformity of flow within a vapor deposition process chamber.

### BACKGROUND

In known chemical vapor deposition processes, the uniformity of the flow distribution within the process chamber affects the uniformity of the thickness of the deposited film. Typically, the gas flow through the process chamber is not uniform and therefore, the gas flow across the wafer surface in the process chamber is not uniformly distributed. When gas flow is not uniform, device performance can be negatively affected and the flatness of the wafer can be diminished. For example, a high gas velocity at the wafer surface results in a thinned boundary layer, faster silicon precursor gas species transport, and an increased growth rate as compared to areas having a lower flow rate.

A conventional system for controlling the uniformity of flow distribution within a process chamber is shown in FIG. 1. FIG. 1 is a schematic illustration of a system 100 coupled to a reaction chamber 101 for supplying a reactant gas to reaction chamber 101. A plurality of gas supply pipes, 102, 103, and 104, each coming from a respective gas source, converge at a single reactant gas supply source pipe 105. Gas flow regulators 106, 107, and 108 are provided on each of the gas supply pipes 102, 103, and 104 to adjust a flow of a gas therethrough. The gas flow regulators 106, 107, and 108 are controlled by a controller 115, enabling the overall flow rate of the reactant gas supplied to the process chamber 101 to be controlled to improve uniformity. Gas supply pipe 105 branches into a plurality of gas supply branch pipes 110. Supply branch pipes 110 are connected to a plurality of gas chambers 130 inside an inlet 135. Regulators 120 continuously control gas flow through each supply branch pipe 110. Regulators 120 are controlled by the controller 115, again controlling gas flow to improve uniformity of flow to gas chambers 130 where each regulator 120 may be controlled independently by controller 115.

Although system 100 may assist in controlling the flow distribution of gas in process chamber 101 overall, system 100 is large in size and difficult to implement. For example, manufacturing and implementation of supply branch pipes 110 and regulators 120 is difficult and expensive.

Thus, a need exists for an efficient distribution manifold that enables improved uniformity of flow in the process chamber.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a gas distribution manifold for a chemical vapor deposition reactor includes a first gas distribution zone including a central gas port located in a central portion of the manifold and in fluid communication with a first gas supply conduit. The gas distribution manifold also includes a second gas distribution zone including at least two intermediate ports adjacent the central gas port and in fluid communication with a second gas supply conduit that is separate from the first gas supply conduit. The gas distribution manifold further includes a third gas distribution zone including at least two outer ports, each one of the outer ports spaced from the central gas port by one of the intermediate ports and in fluid communication with a third gas supply conduit separate from the first and second gas supply conduits. Moreover, the gas distribution manifold includes a fourth gas distribution zone comprising at least two edge ports, each edge port being spaced from the central outlet port by at least one of the intermediate and outer ports, and in fluid communication with a fourth gas supply conduit separate from the first, second and third gas supply conduits. Each of the first, second, third and fourth gas supply conduits are defined by channels formed within the manifold.

In another aspect, a method for manufacturing a gas distribution manifold for a chemical vapor deposition reactor is disclosed. The method includes forming a first gas supply conduit in the manifold to be in fluid communication with a central gas outlet port located in a central portion of the manifold to define a first gas distribution zone. The method also includes forming a second gas supply conduit that is separate from the first gas supply conduit to be in fluid communication with at least two intermediate outlet ports located on opposite sides of the central gas outlet port to define a second gas distribution zone. The method further includes forming a third gas supply conduit separate from the first and second gas supply conduits to be in fluid communication with at least two outer outlet ports, each one of the outer outlet ports located such that the intermediate outlet ports are located between the central gas outlet port and one of the outer outlet ports to define a third gas distribution zone. The method additionally includes forming a fourth gas supply conduit separate from the first, second and third gas supply conduits to be in fluid communication with at least two edge outlet ports, the edge outlet ports located more distal from the central outlet port than the outer outlet ports to define a fourth gas distribution zone. Each of the first, second, third and fourth gas supply conduits are channels created within the manifold.

In yet another aspect, a chemical vapor deposition system is disclosed. The chemical vapor deposition system includes a gas distribution manifold. The gas distribution manifold includes a first gas distribution zone including a central gas port located in a central portion of the manifold and in fluid communication with a first gas supply conduit. The gas distribution manifold also includes a second gas distribution zone including at least two intermediate ports adjacent the central gas port and in fluid communication with a second gas supply conduit that is separate from the first gas supply conduit. The gas distribution manifold further includes a third gas distribution zone including at least two outer ports, each one of the outer ports spaced from the central gas port by one of the intermediate ports and in fluid communication with a third gas supply conduit separate from the first and second gas supply conduits. The gas distribution manifold moreover includes a fourth gas distribution zone comprising at least two edge ports, each edge port being spaced from the central outlet port by at least one of the intermediate and outer ports, and in fluid communication with a fourth gas supply conduit separate from the first, second and third gas supply conduits. Each of the first, second, third and fourth gas supply conduits are defined by channels formed within the manifold. The chemical vapor deposition system also includes a chemical vapor deposition chamber downstream of the manifold and in fluid communication therewith.

### BRIEF DESCRIPTION OF THE DRAWINGS

FIG. 1 is a schematic illustration of a conventional system for controlling the uniformity of flow distribution within a process chamber.

FIG. 2 illustrates a perspective view of a process chamber for a chemical vapor deposition process and an injection cap.

FIGS. 3-5 illustrate perspective views of a gas distribution manifold.

FIG. 6 is a flow diagram for manufacturing a gas distribution manifold.

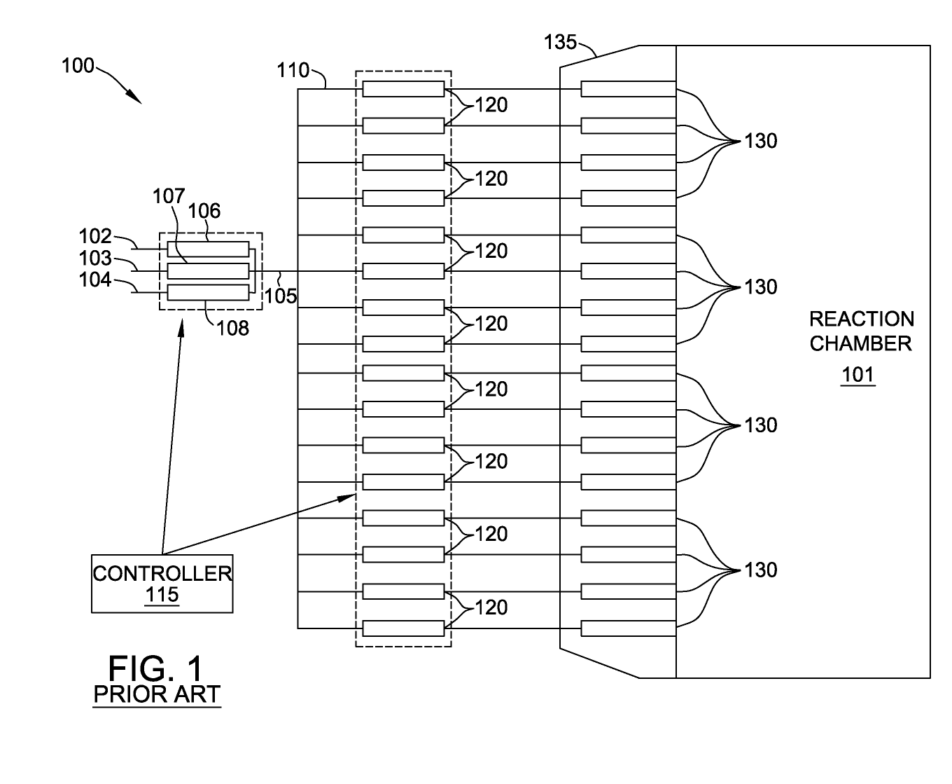

### DETAILED DESCRIPTION

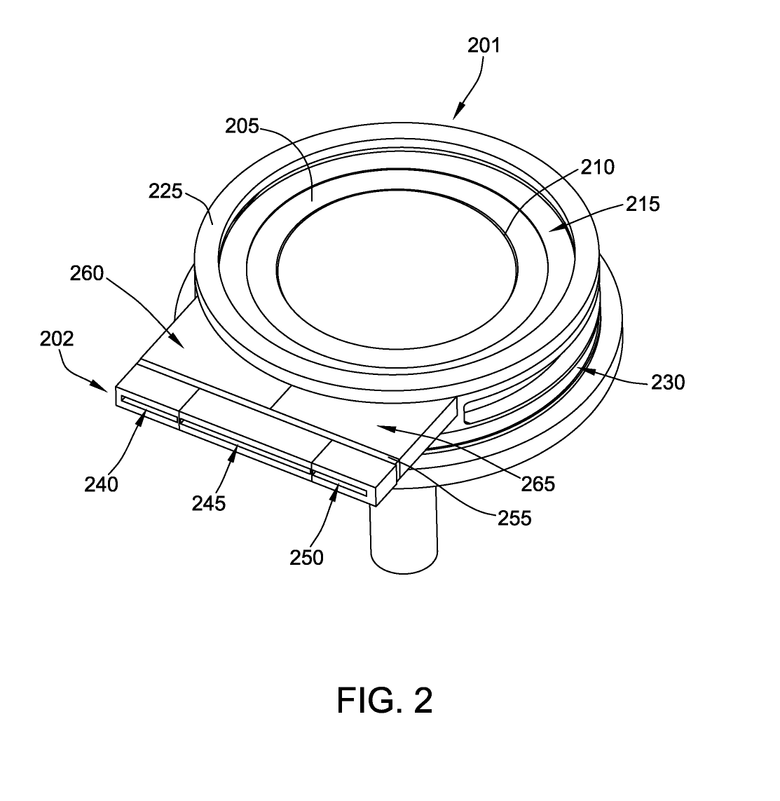

FIG. 2 illustrates a process chamber 201 for a chemical vapor deposition process attached to an injection cap 202 for providing a gas to process chamber 201. Process chamber 201 is configured to support a wafer 205 on a susceptor 210. A preheat ring 215 may be provided to surround the side periphery of susceptor 210 for providing heat treatment with an even temperature distribution. An upper liner 225 and a lower liner 230 are configured to reduce contamination into the inner wall of process chamber 201 and prevent adhesion of wafer 205 to the wall of process chamber 201.

Injection cap 202 is configured to allow for controlled gas flow entering process chamber 201. Accordingly, as further detailed herein, a flow of gas is supplied through a plurality of injection zones to improve the uniformity of the gas flow in the process chamber 201. In the illustrated embodiment, the injection zones include an injection cap first zone 240, an injection cap second zone 245, and an injection cap third zone 250. In other embodiments, additional zones may be included to further distribute the flow of gas within the injection cap. A baffle plate 255 may be included downstream of the injection cap zones, to even further distribute the flow of gas. Downstream from the baffle plate 255 injection inserts, for example left injection insert 260 and right injection insert 265, are included to still further distribute the flow of gas.

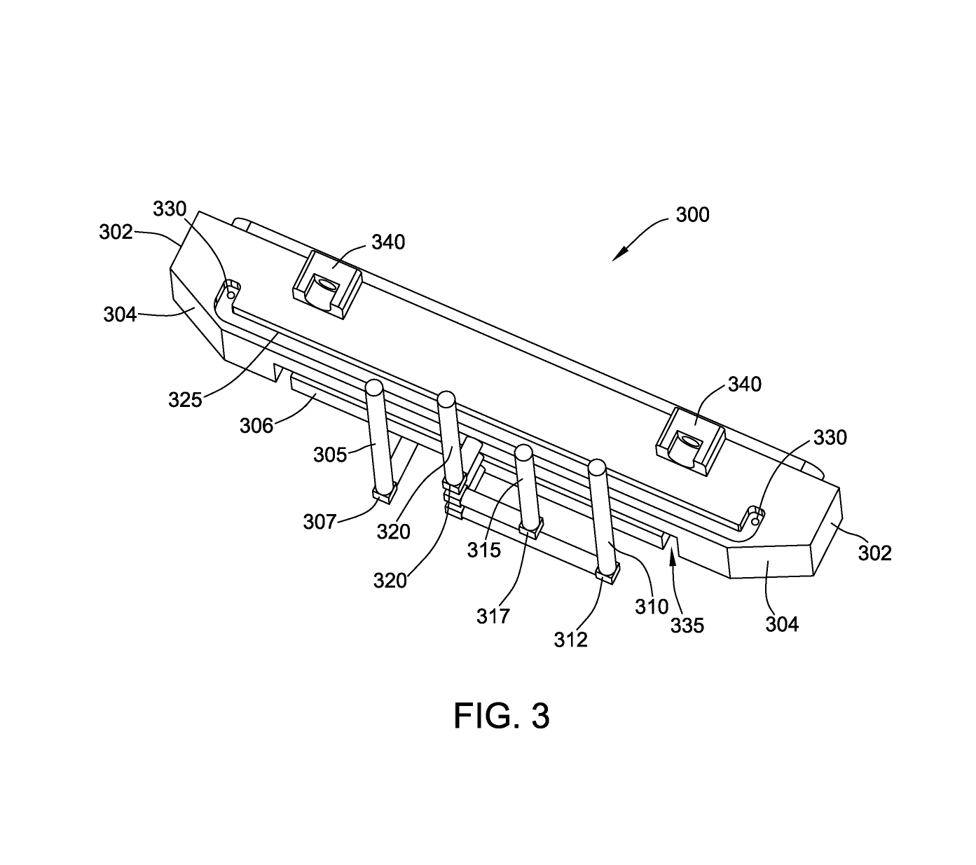

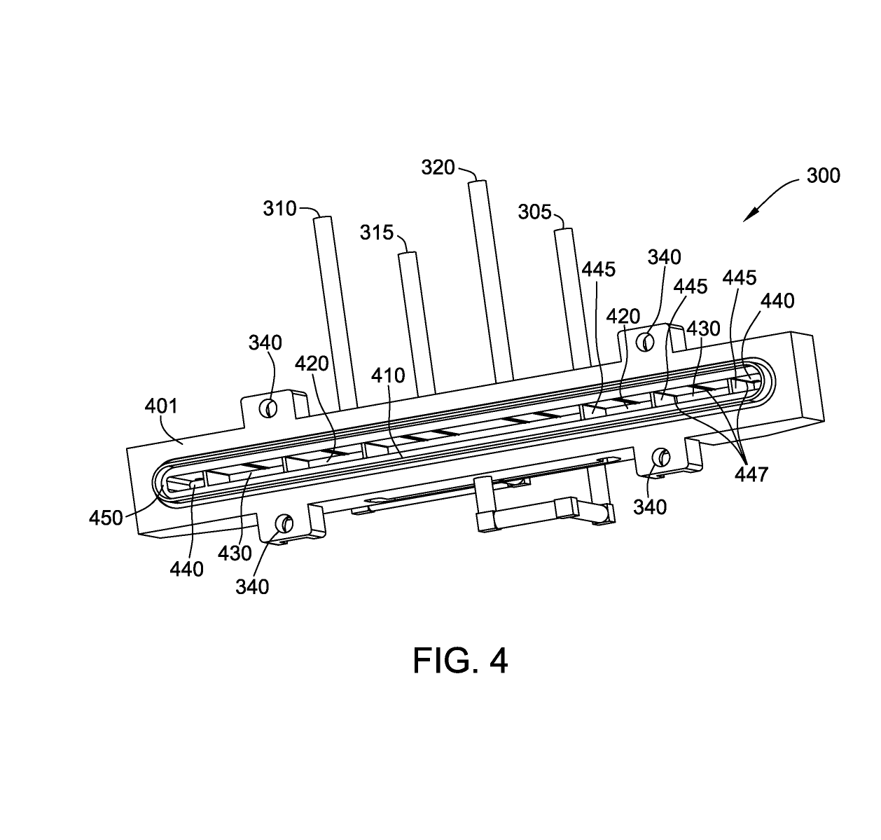

Referring now to FIG. 3, a gas distribution manifold 300 in accordance with an embodiment of the disclosure is shown. In particular, FIG. 3 shows a perspective view of the manifold 300 from an underside thereof. As used herein, the term “underside” refers to a lower side of the manifold 300 when the manifold 300 is in its upright configuration, as it would be in use. The gas distribution manifold 300 has hexagonal shape cross section, with a planar face 401 (FIG. 4) for coupling with the process chamber 201. Each of the lateral faces 302 are substantially perpendicular to the planar face 401. Angled faces 304 extend from the lateral faces 302 at angles, respectively. A distal face 306 extends between the angled faces 304 and is substantially parallel to the planar face 401.

Manifold 300 is fabricated from a material suitable for use with the gas to be supplied therethrough. In some embodiments, the manifold 300 is fabricated from a metal, metal alloy, plastic, composite, laminate, or combinations thereof. In one preferred embodiment, manifold 300 is fabricated from stainless steel. In other embodiments, manifold 300 may be fabricated from any suitable material that allows manifold 300 to function as described herein.

Gas distribution manifold 300 is in fluid communication with a plurality of gas supply conduits for supplying the gas therethrough. The gas supply conduits include a first supply conduit 305, a second supply conduit 310, a third supply conduit 315, and a fourth supply conduit 320. Each of the gas supply conduits may supply different component gases, combinations of component gases, or the same component gas depending on the requirements of the process chamber. Each supply conduit is in fluid communication with a respective first, second, third, and fourth flow controller (307, 312, 318 and 322) for individually controlling the supply of gas through each supply conduit, which may be mass flow controllers or the like.

Manifold 300 includes a first channel 325 in fluid communication with fourth supply conduit 320. The channel 325 is configured distribute gas supplied from the fourth supply conduit 320 into and through manifold 300 to two edge ports 440 (FIG. 4). Gas flowing through first channel 325 enters flows through first channel 330 before being distributed to the edge ports 440. Without being bound to a particular theory, it is believed that the flow of gas within first channel 325 is distributed evenly within the channel 325, for example due to back pressure and turbulence within the channel. In one embodiment, first channel 325 is machined into manifold 300 using any machining tool capable of precisely creating first channel 325 in the materials of manifold 300, for example by use of a CNC machine, waterjet, milling device, router or the like. After machining, channel 325 is covered with a sealing surface (not shown) that is affixed to manifold 300 to thereby create a conduit for the gas flow. The sealing surface may be any material capable of creating a sealed conduit. For example, the sealing material may be the same material used to fabricate the manifold 300, or other suitable material. The sealing surface may be affixed to the manifold 300 by welding, adhesives, fasteners, or any other method which securely seals the surface to manifold 300 and allows first channel 325 to function as described herein.

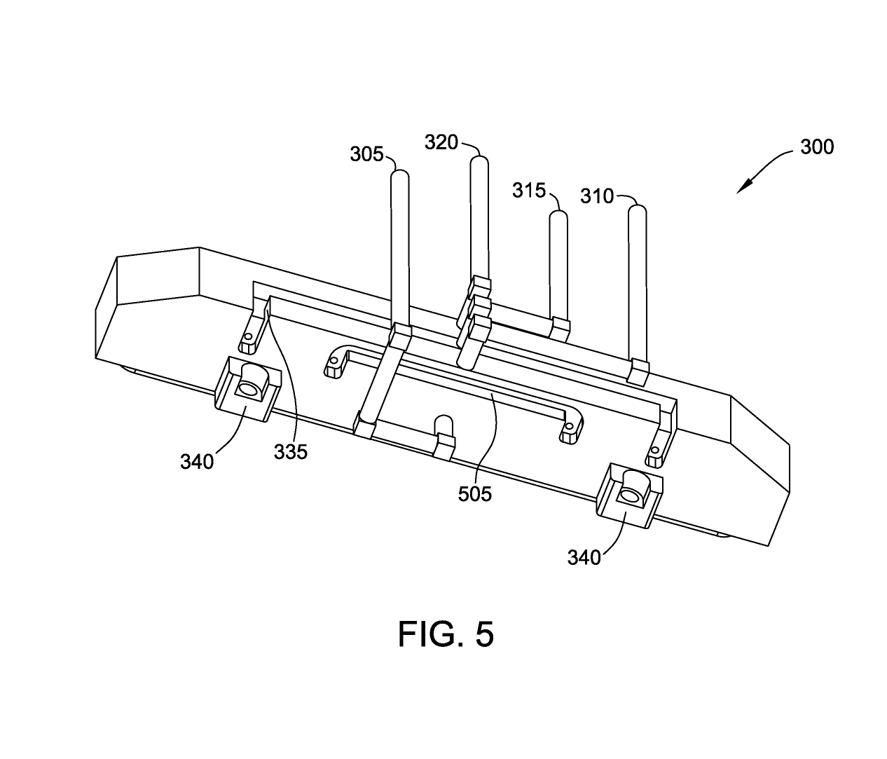

A second channel 335 is located in the distal face 306. The second channel 335 provides similar functionality as first channel 325, but is in fluid communication with the third supply conduit 315. Outer ports 430 associated with second channel 335 are best shown in FIG. 4. Second channel 335 may be machined into manifold 330 using a process similar to, or different than, the process used to create first channel 325. A third channel 505 is shown in FIG. 5. The third channel is machined in a face of the manifold 300 opposite the first channel 330. The third channel 505 provides similar functionality to the first channel 325. However, second supply conduit 310 is in fluid communication with third channel 505. Third channel 505 distributes gas flowing through second supply conduit 310 to intermediate ports 420.

With reference to FIG. 4, the central gas distribution zone includes a central port 410 is located in a central portion of manifold 300 and in fluid communication with the first gas supply conduit 305. The first gas supply conduit supplies gas through an internal channel (not shown) through manifold 300 to central port 410. A second gas distribution zone includes at least two intermediate ports 420 adjacent first gas distribution zone 410 and in fluid communication with a second gas supply conduit 310 that is separate from the first gas supply conduit. Second supply conduit 310 is in fluid communication with the third channel (FIG. 3). A third gas distribution zone 430 includes at least two outer ports 430. Each one of the outer ports 430 is spaced apart from first gas distribution zone 410 by one of the intermediate ports 420 of second gas distribution zone 420 and in fluid communication with a third gas supply conduit separate from the first and second gas supply conduits. In the exemplary embodiment, the third gas supply conduit is third supply conduit 315. Third supply conduit 315 is in fluid communication with second channel 335 (FIG. 3) for distributing gas flowing through third supply conduit 315.

A fourth gas distribution zone includes at least two edge ports 440, each of the edge ports 440 is spaced apart from the first gas distribution zone 410 by at least one of the ports (420, 430) associated with the second gas distribution zone and third gas distribution zone. The edge ports 440 are in fluid communication with a fourth gas supply conduit 320, which is separate from the first, second and third gas supply conduits 305, 310 and 315. In the exemplary embodiment, the fourth gas supply conduit 320 is in fluid communication with first channel 325 (FIG. 3) for distributing gas flowing through fourth supply conduit 320.

The ports of the first gas distribution zone, second gas distribution zone, third gas distribution zone, and fourth gas distribution zone 440 are separated by walls 445. Walls 445 are configured to provide separation of the gases flowing within each of the zones, thus forming the central port 410, intermediate ports 420, outer ports 430 and edge ports 440. In some embodiments, walls 445 are also configured to be removable, allowing for the location of each port to be altered, expanded or reduced. For example, walls 445 are supported by grooves 447. The grooves 447 are distributed about the length of manifold 300 to allow the walls 445 to be placed in various locations, depending upon the requirements of the user. To further provide the ability to vary the dimensions of the ports, each of the walls 445 may be a different widths (thickness). As such, a thicker wall may occupy more space within a particular zone and thereby reduce the overall size of the respective port (as compared to a thinner wall).

Adjusting the location of the walls 445 may provide the user with an additional means of controlling the uniformity of gas flow through manifold 300 and within process chamber 201. Walls 445 may be fabricated from any material suitable for use with the process gas(es) contacted. For example, each of the walls 445 may be fabricated from the same material as manifold 300 or any other material that allows walls 445 to function as described herein. In some embodiments, walls 445 are fabricated from a metal, metal alloy, plastic, composite, laminate, or combinations thereof.

Manifold 300 is placed in fluid communication with the process chamber 201 by coupling the planar face 401 of manifold 300 to the process chamber 201 using connections 340. In the exemplary embodiment, four connections 340 are used to connect to the process chamber 201 by way of a fasteners (not shown). Suitable fasteners may include bolts, pins, screws, adhesives or any other method capable of connecting manifold 300 that allows the device to function as described herein.

In one embodiment, manifold 300 also includes a seal 450 which provides a substantially airtight seal with process chamber 201 when coupled together. Seal 450 may be fabricated from any material that allows for sealing between the process chamber and manifold 300, such as rubber, polyurethane other flexible materials or the like. The manifold 300 may be coupled to the process chamber 201 directly, or by way of injection cap 202. For example, in one embodiment, the injection cap 202 of FIG. 2 is replaced by the manifold 300. In another embodiment, the manifold 300 is coupled to the baffle plate 255 or the left and right injection inserts 260, 265.

In operation, to control the gas flow within process chamber 201, an operator may adjust the gas flows out of the central port 410, intermediate ports 420, outer ports 430 and edge ports 440 by use of the respective flow controllers 307, 312, 317 and 322. For example, to reduce gas flow from central port 410, the flow controller 317 is adjusted to restrict an outflow of gas, thus reducing the gas flow in the central region of the process chamber 201. Accordingly, adjusting the flow controller 317 to allow increased flow may thereby increase the gas flow in the central region of the process chamber 201. Similarly, flow controllers 307, 312 and 322 may be adjusted to increase or decrease the flow of gas therethrough, and thus the flow of gas in the respective areas of the process chamber 201. Accordingly, one or more of the flow controllers may be adjusted sequentially or simultaneously to achieve the desired gas flow within the process chamber.

In some embodiments, the flow controllers 307, 312, 317 and 322 are controlled automatically by way of a computer controller or the like. In such embodiments, one or more growth parameters (i.e., thickness, flatness, etc.) of the wafer may be inspected, and the gas flows may be automatically adjusted to even out the growth of the wafer. In other embodiments, an operator may manually adjust one or more of the flow controllers to affect the growth parameters of the wafer in the process chamber 201.

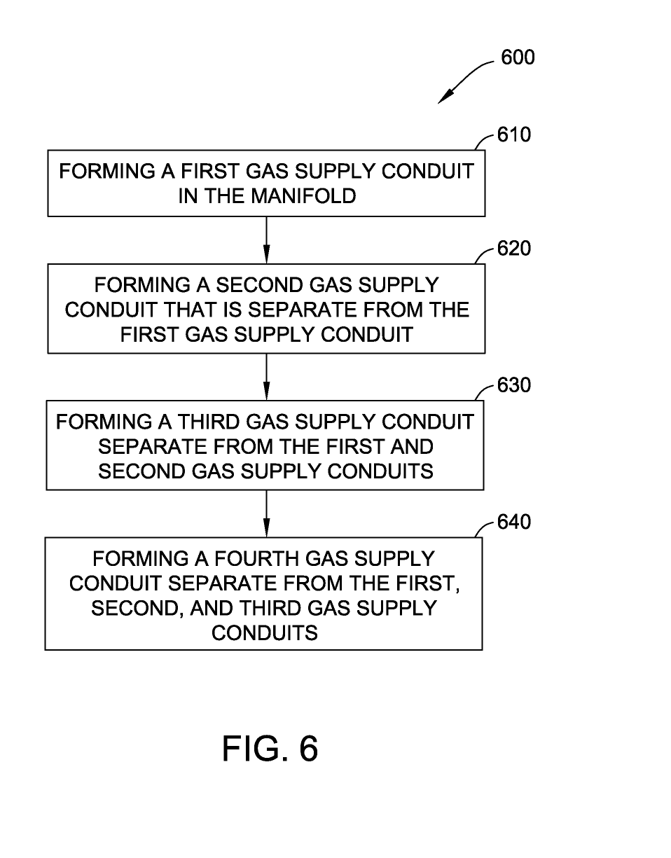

Referring now to FIG. 6, an exemplary method 600 for manufacturing a gas distribution manifold 300 is shown. In this embodiment, manifold 300 is manufactured by first forming 610, such as by machining, a first gas supply conduit in the manifold to be in fluid communication with a central gas outlet port located in a central portion of the manifold to define a first gas distribution zone. Forming 610 refers generally to creating a fluid communication between first gas central port 410 (FIG. 4) and first supply conduit 305.

Manufacturing the manifold 300 also includes forming 620 a second gas supply conduit in manifold 300 that is separate from the first gas supply conduit. The second gas supply conduit is formed to be in fluid communication with at least two intermediate outlet ports located on opposing sides of the central gas outlet port to define a second gas distribution zone. Forming 620 refers to creating a fluid communication between the second gas distribution zone including a plurality of intermediate outlet ports 420, and second supply conduit 310 (FIG. 3) by way of third channel 505 (FIG. 5).

Manufacturing manifold 300 also includes forming 630 a third gas supply conduit separate from the first and second gas supply conduits to be in fluid communication with at least two outer outlet ports. Each one of the outer outlet ports located such that the intermediate outlet ports are located between the central gas outlet port and one of the outer outlet ports to define a third gas distribution zone. Forming 630 refers to creating a fluid communication between third gas distribution zone, including a plurality of outer outlet ports 430 (FIG. 4), and third supply conduit 315 (FIG. 3) by way of second channel 335 (FIG. 3). Further, the method includes forming 640 a fourth gas supply conduit separate from the first, second and third gas supply conduits to be in fluid communication with at least two edge outlet ports. The edge outlet ports are located more distal from the central outlet port than the outer outlet ports to define a fourth gas distribution zone. Forming 640 refers to creating a fluid communication between fourth gas distribution zone including a plurality of edge outlet ports 440 (FIG. 4) and fourth supply conduit 320 (FIG. 3) by way of first channel 325 (FIG. 3).

Embodiments of the system, systems and methods for gas distribution manifolds for chemical vapor deposition reactors are described above in detail. The system, systems and methods are not limited to the specific embodiments described herein, but rather, components of the systems and system, and/or steps of the methods may be utilized independently and separately from other components and/or steps described herein. For example, the methods may also be used in combination with other systems, methods, and systems, and are not limited to practice with only the systems, methods, and system as described herein. Rather, the exemplary embodiment can be implemented and utilized in connection with many other applications.

Embodiments of the present disclosure provide a gas distribution manifold for a chemical vapor deposition process that provides improved uniformity of flow within the process chamber. Embodiments of the manifold are more compact than typical injector caps because the conduits that distribute the gas are formed within the manifold itself. Further, the use of multiple flow controllers coupled to each of the conduits, and thus the ports, allows for increased control over the flow of gas within the process chamber.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A gas distribution manifold for a chemical vapor deposition reactor comprising:
a first gas distribution zone including a central gas port located in a central portion of the manifold and in fluid communication with a first gas supply conduit,
a second gas distribution zone including at least two intermediate ports adjacent the central gas port and in fluid communication with a second gas supply conduit that is separate from the first gas supply conduit,
a third gas distribution zone including at least two outer ports, each one of the outer ports spaced from the central gas port by one of the intermediate ports and in fluid communication with a third gas supply conduit separate from the first and second gas supply conduits,
a fourth gas distribution zone comprising at least two edge ports, each edge port being spaced from the central outlet port by at least one of the intermediate and outer ports, and in fluid communication with a fourth gas supply conduit separate from the first, second and third gas supply conduits,
wherein each of the first, second, third and fourth gas supply conduits are defined by channels formed within the manifold.

2. The gas distribution manifold according to claim 1 wherein each of the first, second, third and fourth gas distribution zones are separated from one another by walls.

3. The gas distribution manifold according to claim 2 wherein the walls are configured to be removable from the manifold.

4. The gas distribution manifold according to claim 1 wherein each of the first, second, third and fourth gas supply conduits are in fluid communication with respective first, second, third and fourth flow controllers for individually controlling the supply of gas therethrough.

5. The gas distribution manifold according to claim 1 wherein the manifold comprises opposing top and bottom walls and opposing side walls connected to the top and bottom walls, and the top wall at least in part defines one of the first, second, third or fourth gas supply conduits.

6. The gas distribution manifold according to claim 5 further comprising a front wall defining an exit of the central gas outlet port, the intermediate gas outlet ports, the outer outlet ports and the edge outlet ports.

7. The gas distribution manifold according to claim 6 further comprising a rear wall opposite the front wall, the rear wall at least partially defining one of the first, second, third or fourth gas supply conduits.

8. The gas distribution manifold according to claim 5 wherein each of the first, second, third and fourth gas supply conduits are isolated from one another downstream of the first, second, third and fourth flow controllers.

9. The gas distribution manifold according to claim 1 wherein the first, second, third and fourth gas supply conduits are the only gas supply channels defined in the manifold.

10. A method of manufacturing a gas distribution manifold for a chemical vapor deposition reactor, comprising:
forming a first gas supply conduit in the manifold to be in fluid communication with a central gas outlet port located in a central portion of the manifold to define a first gas distribution zone,
forming a second gas supply conduit that is separate from the first gas supply conduit to be in fluid communication with at least two intermediate outlet ports located on opposite sides of the central gas outlet port to define a second gas distribution zone,
forming a third gas supply conduit separate from the first and second gas supply conduits to be in fluid communication with at least two outer outlet ports, each one of the outer outlet ports located such that the intermediate outlet ports are located between the central gas outlet port and one of the outer outlet ports to define a third gas distribution zone,
forming a fourth gas supply conduit separate from the first, second and third gas supply conduits to be in fluid communication with at least two edge outlet ports, the edge outlet ports located more distal from the central outlet port than the outer outlet ports to define a fourth gas distribution zone,
wherein each of the first, second, third and fourth gas supply conduits are channels created within the manifold.

11. The method according to claim 10 wherein at least one of forming one of the first, second, third and fourth gas supply conduits includes cutting a groove in the manifold.

12. The method according to claim 11 further comprising covering the groove with a material to define the respective gas supply conduit.

13. The method according to claim 10 further comprising coupling first, second, third and fourth flow controllers to the respective first, second, third and fourth gas supply conduits for individually controlling a supply of gas therein.

14. The method according to claim 10 wherein each of the first, second, third and fourth gas supply conduits are formed by cutting respective first, second, third and fourth grooves in the manifold, such that each of the grooves are isolated from each other.

15. A chemical vapor deposition system comprising:
a gas distribution manifold including:
a first gas distribution zone including a central gas port located in a central portion of the manifold and in fluid communication with a first gas supply conduit,
a second gas distribution zone including at least two intermediate ports adjacent the central gas port and in fluid communication with a second gas supply conduit that is separate from the first gas supply conduit,
a third gas distribution zone including at least two outer ports, each one of the outer ports spaced from the central gas port by one of the intermediate ports and in fluid communication with a third gas supply conduit separate from the first and second gas supply conduits, and
a fourth gas distribution zone comprising at least two edge ports, each edge port being spaced from the central outlet port by at least one of the intermediate and outer ports, and in fluid communication with a fourth gas supply conduit separate from the first, second and third gas supply conduits,
wherein each of the first, second, third and fourth gas supply conduits are defined by channels formed within the manifold,
a chemical vapor deposition chamber downstream of the manifold and in fluid communication therewith.

16. The chemical vapor deposition system according to claim 15 wherein each of the first, second, third and fourth gas supply conduits are in fluid communication with respective first, second, third and fourth flow controllers for individually controlling the supply of gas in each of the first, second, third and fourth gas supply conduits.

17. The gas distribution manifold according to claim 16 wherein each of the first, second, third and fourth gas supply conduits are isolated from one another downstream of the first, second, third and fourth flow controllers.

18. The chemical vapor deposition system according to claim 15 wherein each of the first, second, third and fourth gas distribution zones are separated from one another by walls.

19. The chemical vapor deposition system according to claim 18 wherein the walls are configured to be removable from the manifold.

20. The chemical vapor deposition system according to claim 15 further comprising a rear wall opposite the front wall, the rear wall at least partially defining one of the first, second, third or fourth gas supply conduits.

21. The chemical vapor deposition system according to claim 15 wherein each of the first, second, third and fourth gas supply conduits are defined by individual grooves in the manifold.
